(19) United States
(12) Patent Application Publication
(10) Pub. No.: US 2019/0363005 A1
(43) Pub. Date: Nov. 28, 2019

(54) METHOD FOR CHANGING EDGE STIR OF SOI BY FILM COATING

(71) Applicant: Shenyang Silicon Technology Co., Ltd., Shenyang (CN)

(72) Inventor: Yang LIU, Wafangdian City (CN)

(73) Assignee: Shenyang Silicon Technology Co., Ltd., Shenyang (CN)

(21) Appl. No.: 16/214,329

(22) Filed: Dec. 10, 2018

(30) Foreign Application Priority Data
May 28, 2018 (CN) 201810521000.4

(51) Int. Cl. H01L 21/762; H01L 21/02; H01L 21/311; H01L 21/66

(52) U.S. Cl. CPC H01L 21/76254; H01L 21/02238; H01L 22/12; H01L 21/0206; H01L 21/31111

(57) ABSTRACT

A method for changing an edge STIR of a silicon-on-insulator (SOI) by film coating, including: using a silicon wafer as a raw material, and performing oxidizing, injecting, bonding, splitting, and film coating in sequence. If a blue film is used, the required thickness of the blue film is 0-0.5 mm; the film is coated to the back surface of the silicon wafer; an oxide layer on the edge of the front surface of the silicon wafer is removed by concentrated hydrofluoric acid; the film on the back surface of the SOI is removed by concentrated SC1; washing is performed by SC1 and SC2, the STIR is smaller than 0.3 μm. According to the present invention, the oxide layer on the edge is removed by using the blue film coating manner, the SITR is relatively small, the chamfering process is replaced, and the STIR of the obtained SOI is better.

### FIELD

The present invention relates to the field of manufacturing of an SOI (Silicon-On-Insulator, and the technology is to introduce a layer of buried oxide between a top silicon and a back substrate), and particularly provides a method for changing edge STIR (local flatness) of the SOI by film coating.

### BACKGROUND

In the prior art, with the continuous development of silicon material processing technologies in China in recent years, people have paid more and more attention to the processing quality and detection methods in wafer processing. The quality testing during processing has become very important. The detection on several important geometric parameters characterizing wafer processing parameters including the curvature, the thickness and the total thickness variation as well as the detection methods particularly draw the attention of silicon wafer manufacturers and device manufacturers. Highly-automated wafer detection systems have been introduced constantly. For example, ADE Company, TENCOR Company, TROPEL Company and SILTEC Company in the US have developed the automatic detection systems which can meet the requirements of users on wafer detection, for example, the 700-type Wafer Detection System of the ADE Company. The system is a modular structure and can also measure multiple parameters such as the curvature (TIR), the thickness (FPD), and the total thickness variation (LSL) in addition to the curvature, the thickness, and the total thickness variation of the wafer. The system can also perform various detections on the resistivity, the doping type, the surface focus brightness inspection and the like, is highly automated and has a processing capacity of 60 wafers per hour. There is also the 900-type Auto Sort Wafer Detection System of the TROPEL Company, which is said to be the current only automatic wafer detection system with the most detection functions. In the processing of the wafers, the need for wafer detection and the degree of application vary depending on different manufacturers.

Therefore, it is expected to obtain a method which has high operability and is capable of flexibly changing the edge STIR of the SOI.

### SUMMARY

An objective of the present invention is to provide a method for changing an edge STIR of an SOI by film coating.

The present invention provides a method for changing an edge STIR of an SOI by film coating, which comprises: using a silicon wafer as a raw material, and performing oxidizing, injecting, bonding, splitting, and film coating in sequence; wherein: the technical requirements on film coating are as below: the front surface and back surface of the SOI cannot be scratched in the film coating process using a film coating device; when the device adsorbs the silicon wafer, the silicon wafer cannot be dropped; the required thickness of a blue film is 0-0.5 mm, and the blue film commonly used in the industry of semiconductors can be used; the film is coated to the back surface of the silicon wafer; at this point, the film exists on the back surface of the silicon wafer; then the oxide layer on the edge of the front surface of the silicon wafer is removed by using concentrated hydrofluoric acid (at this time, the film exists on the back surface of the silicon wafer, thus the back surface of the SOI is not damaged); the film on the back surface of the SOI is removed by concentrated SC1; then washing is performed by SC1 and SC2 (according to an industrial standard), the edge STIR of the SOI is tested by a 9600 device, and at this point, the STIR is smaller than 0.3 μm. The resistivity and crystal orientation of the silicon wafer raw material are selected according to actual needs.

The method for changing an edge STIR of an SOI by film coating has the preferred technical requirements as follows.

The oxidizing comprises the steps of: oxidizing one side surface of the silicon wafer raw material to obtain the silicon wafer with an oxide layer, then cleaning to remove surface contaminants, then testing the surface particle condition, a thickness of the oxide layer and other various parameters of the silicon wafer with the oxide layer by using a test device, and selecting the silicon wafer meeting the requirements as standby.

The injecting comprises the steps of: injecting H⁺ into the silicon wafer with an oxide layer and injecting to the desired depth of a product; injecting according to the specific injection conditions, i.e., the requirements on energy, a dose, a beam size and an angle, and after the injection, cleaning according to the following requirements: using concentrated sulfuric acid, SC1 and SC2 for cleaning; in order to remove surface contaminants, testing surface particles, geometric parameters and other various parameters of the silicon wafer with the oxide layer by using a test device, and selecting the silicon wafer meeting the conditions (the conditions cannot be unified due to different products) as standby.

The bonding process comprises the steps of: preparing another silicon wafer, which is an oxide wafer or a polished wafer, selecting a resistivity and a crystal orientation of the another silicon wafer according to requirements, after cleaning the surface of the another silicon wafer to remove a surface natural oxide layer and surface layer contaminants, testing the surface particle condition of the silicon wafer by using the test device, and bonding the silicon wafer meeting the requirements (different products have different particle requirements and cannot achieve specific data) to the silicon wafer subjected to injection, using certain activating time for the two wafers, and performing low-temperature annealing at 100-350° C. on the obtained bonded wafer, thereby obtaining the bonded wafer with injection.

The splitting process comprises: placing the bonded wafer into a splitting machine, and processing with the following splitting process: raising the temperature of the silicon wafer in a cavity to 100-200° C., and performing temperature preservation for 10-30 min; turning on a microwave magnetic control head for splitting for 1-10 min, and obtaining an SOI product after splitting.

The specific requirement on the low-temperature annealing is that low-temperature annealing is performed after bonding and before splitting, and a temperature for the low-temperature annealing is 100-300° C. for 2-5 hours.

The design principle and beneficial effects of the present invention are as follows.

1. In the present invention, the silicon wafer is subjected to oxidizing, injection, bonding, low-temperature annealing and the like to obtain a bonded silicon wafer. Then the bonded wafer is split using the microwave splitting technology to form the SOI structure. The film is coated to the back surface of the SOI. The oxide layer on the edge of the front surface is removed with concentrated hydrofluoric acid. At this point, the oxide layer on the back layer still remains, and then the film is removed again to obtain the SOI having the STIR smaller than 0.3 μm. The process is normally performed by chamfering, so the SITR is relatively large. The oxide layer on the edge is removed by using the blue film coating manner, and the SITR is relatively small.

2. The method for changing an edge STIR of an SOI by film coating according to the present invention has an obviously better technical effect than the chamfering technology. The STIR of the SOI subjected to the chamfering process is relatively large and is 0.5 μm or more. The present invention replaces the chamfering process, and the STIR of the SOI obtained is better.

3. The method for changing an edge STIR of an SOI by film coating is suitable for industrial production and can be used for production in batches. The invention replaces the chamfering process by using the film coating technology, thereby improving the efficiency and releasing the production capacity.

Compared with the prior art, the present invention has an obviously better technical effect, and is expected to have relatively large economic values and social values.

### BRIEF DESCRIPTION OF THE DRAWINGS

FIG. 1 is a process flowchart of a method for changing an edge STIR of an SOI by film coating.

FIG. 2 is a process flowchart of a comparative example in the prior art.

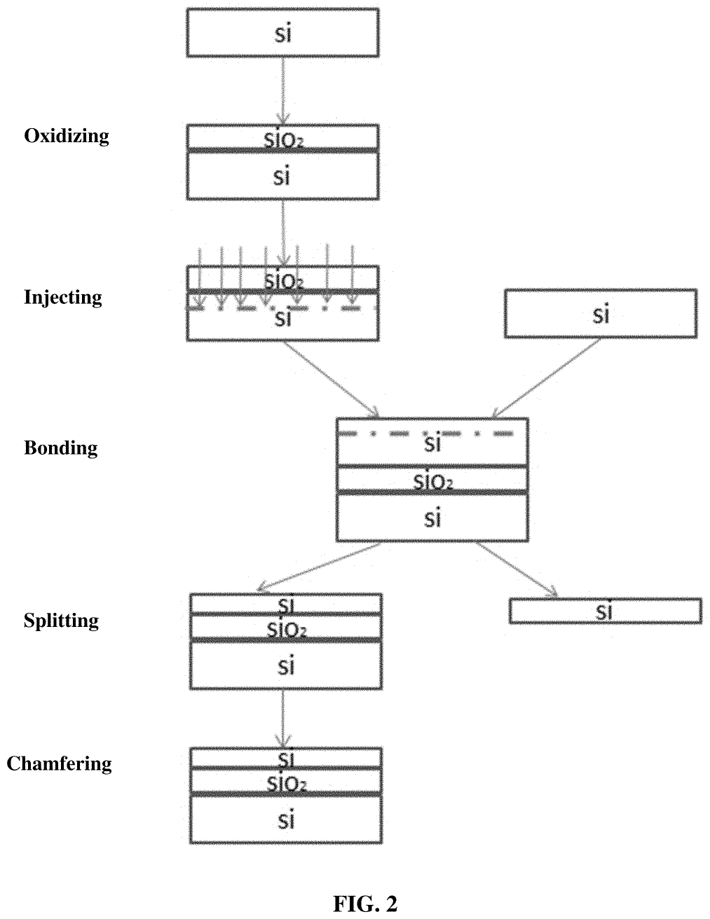

### DETAILED DESCRIPTION

### Embodiment 1

A method for changing an edge STIR of an SOI by film coating comprises: using a silicon wafer as a raw material, and performing oxidizing, injecting, bonding, splitting, and film coating in sequence; wherein: the technical requirements on film coating are as below: the front surface and back surface of the SOI cannot be scratched in the film coating process using a film coating device; when the device adsorbs the silicon wafer, the silicon wafer cannot be dropped; the required thickness of a blue film is 0-0.5 mm, and the blue film commonly used in the industry of semiconductors can be used; the film is coated to the back surface of the silicon wafer; at this point, the film exists on the back surface of the silicon wafer; then an edge oxide layer on the front surface of the silicon wafer is removed by using concentrated hydrofluoric acid (at this time, the film exists on the back surface of the silicon wafer, thus the back surface of the SOI is not damaged); the film on the back surface of the SOI is removed by concentrated SC1; then washing is performed by SC1 and SC2 (according to an industrial standard), the edge STIR of the SOI is tested by a 9600 device, and at this point, the STIR is smaller than 0.3 μm. The resistivity and crystal orientation of the silicon wafer raw material are selected according to actual needs.

In the SC1 cleaning liquid, the ratio of ammonia water to hydrogen peroxide to water is 1:1:5-1:2:7.

In the SC2 cleaning liquid, the ratio of hydrogen chloride to hydrogen peroxide to water is 1:1:6-1:2:8.

The concentration of hydrogen chloride is 37%, the concentration of ammonia water is 27%, and the concentration of hydrogen peroxide is 30%.

The oxidizing process comprises the steps of: oxidizing one side surface of the silicon wafer raw material to obtain the silicon wafer with an oxide layer, then cleaning to remove surface contaminants, then testing the surface particle condition, a thickness of the oxide layer and other various parameters of the silicon wafer with the oxide layer by using a test device, and selecting the silicon wafer meeting the requirements as standby.

The injecting process comprises the steps of: injecting H⁺ into the silicon wafer with an oxide layer and injecting to the desired depth of a product; injecting according to the specific injection conditions, i.e., the requirements on energy, a dose, a beam size and an angle, and after the injection, cleaning according to the following requirements: using concentrated sulfuric acid, SC1 and SC2 for cleaning; in order to remove surface contaminants, testing surface particles, geometric parameters and other various parameters of the silicon wafer with the oxide layer by using a test device, and selecting the silicon wafer meeting the conditions (the conditions cannot be unified due to different products) as standby.

The bonding process comprises the specific steps preparing another silicon wafer, which is an oxide wafer or a polished wafer, selecting a resistivity and a crystal orientation of the another silicon wafer according to requirements, after cleaning the surface of the another silicon wafer to remove a surface natural oxide layer and surface layer contaminants, testing the surface particle condition of the silicon wafer by using the test device, bonding the silicon wafer meeting the requirements (different products have different particle requirements and cannot achieve specific data) to the silicon wafer subjected to injection, using certain activating time for the two wafers, and performing low-temperature annealing at 100-350° C. on the obtained bonded wafer, thereby obtaining the bonded wafer with injection.

The splitting process comprises: placing the bonded wafer into a splitting machine, and processing with the following splitting process: raising the temperature of the silicon wafer in a cavity to 100-200° C., and performing temperature preservation for 10-30 min; turning on a microwave magnetic control head for splitting for 1-10 min, and obtaining an SOI product after splitting.

The specific requirement on the low-temperature annealing is that low-temperature annealing is performed after bonding and before splitting, and a temperature for the low-temperature annealing is 100-300° C. for 2-5 hours.

The design principle and beneficial effects of the present invention are as follows.

1. In the present invention, the silicon wafer is subjected to oxidizing, injection, bonding, low-temperature annealing and the like to obtain a bonded silicon wafer. Then the bonded wafer is split with the microwave splitting technology to form the SOI structure. The film is coated to the back surface of the SOI. The oxide layer on the edge of the front surface is removed with concentrated hydrofluoric acid. At this point, the oxide layer on the back layer still remains, and then the film is removed again to obtain the SOI having the STIR smaller than 0.3 μm. The process is normally performed by chamfering, so the SITR is relatively large. The oxide layer on the edge is removed by using the blue film coating manner, and the SITR is relatively small.

2. The method for changing an edge STIR of an STIR by film coating according to the present invention has an obviously better technical effect than the chamfering technology. The STIR of the SOI subjected to the chamfering process is relatively large and is 0.5 μm or more. The present invention replaces the chamfering process, and the STIR of the SOI obtained is better.

3. The method for changing an edge STIR of an SOI by film coating is suitable for industrial production and can be used for production in batches. The invention replaces the chamfering process by using the film coating technology, thereby improving the efficiency and releasing the production capacity.

Compared with the prior art, the present invention has an obviously better technical effect, and is expected to have relatively large economic values and social values.

### Embodiment 2

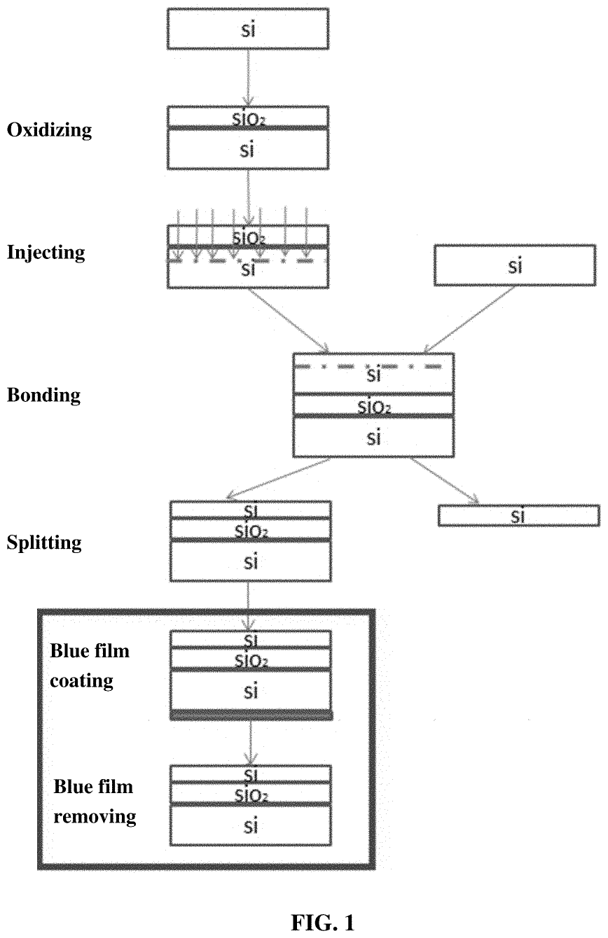

For a method for changing an edge STIR of an SOI by film coating (as shown in FIG. 1, the contents in the large box in the lower left corner of the figure are the key innovations of the present invention), the specific explanation is as follows.

1. An 8-inch P-type silicon wafer of which the crystal orientation can be <100> or <111> is taken, and the resistivity is selected from light doping to high resistance.

2. An oxide layer (silicon dioxide) is prepared on the silicon wafer: oxidizing is performed on the surface of one side of the silicon wafer in step 1 (or both wafers may be oxidized according to actual process conditions); the silicon wafer with the oxide layer is obtained (the silicon dioxide is used as the oxide layer of the SOI); the oxidizing is performed by a conventional process, and the thickness of the prepared oxide layer (silicon oxide) is >0-3000 nm. The prepared silicon wafer with the oxide layer is sequentially cleaned by SC1 and SC2 to remove the contaminants on the surface of the silicon wafer. Then a test device is used to measure the particle condition of the surface of the silicon wafer, and the test device is used to test the thickness and other various parameters (such as the particles of the silicon oxide layer, and electrical parameters) of the silicon oxide, and the desired silicon wafer is selected for the followed steps.

3. The silicon wafer or the polished wafer with the oxide layer is subjected to injection, and the injection depth is performed according to the requirements.

4. An 8-inch bare wafer of which the resistivity and crystal orientation are selected according to the requirements is selected. Surface cleaning by DHF, SC1 and SC2 is carried out in sequence to remove a natural oxide layer and possible surface contaminants. The test device is used to test the particle condition of the surface of the silicon wafer, and the silicon wafer meeting the requirements is selected as standby.

5. Bonding process: the silicon wafer injected with hydrogen ions in step 3 is bonded to the silicon wafer meeting the requirements in step 4, and certain activating time is required. Then low-temperature annealing is performed for certain annealing time, and the annealing temperature is controlled between 100 and 350° C. After the annealing, the bonded wafer with injection is obtained.

6. Microwave splitting is performed on the bonded wafer: the microwave splitting technology of Shenyang Silicon-Based Technology Co., Ltd., is adopted, and the desired splitting process program is selected to split the bonded wafer. The SOI product is obtained.

7. Film coating process: 8-inch SOI wafer is obtained by step 6. The back surface of the silicon wafer is coated with a professional film coating device, and then etching is performed by concentrated hydrofluoric acid to remove the oxide layer on the edge of the front surface. Then by using concentrated SC1, the film on the back surface of the silicon wafer is removed. Afterwards, the silicon wafer is cleaned (cleaning by SC1 and SC2), and the SOI of which the edge STIR is smaller than 0.3 μm can be obtained.

8. The 8-inch SOI is obtained by step 6, and the SOI wafer is recycled according to company regulations.

### COMPARATIVE EXAMPLE

1. An 8-inch P-type silicon wafer of which the crystal orientation can be <100> or <111> is taken, and the resistivity is selected from light doping to high resistance.

2. An oxide layer (silicon dioxide) is prepared on the silicon wafer: oxidizing is performed on the surface of one side of the silicon wafer in step 1 (or both wafers may be oxidized according to actual process conditions); the silicon wafer with the oxide layer is obtained (SiO is used as the BOX layer of the SOI); the oxidizing is performed by a conventional process; and the thickness of the prepared oxide layer (silicon oxide) is >0-3000 nm. The prepared silicon wafer with the oxide layer is sequentially cleaned by SC1 and SC2 to remove the contaminants on the surface of the silicon wafer. Then a test device is used to measure the particle condition of the surface of the silicon wafer, the test device is used to test the thickness of the silicon oxide and other various parameters (such as the particles of the silicon oxide layer, and electrical parameters), and the desired silicon wafer is selected for the followed steps.

3. The silicon wafer or the polished wafer with the oxide layer is subjected to injection, and the injection depth is performed according to the requirements.

4. An 8-inch bare wafer of which the resistivity and crystal orientation are selected according to the requirements is selected. The surface cleaning by DHF, SC1 and SC2 is carried out in sequence to remove a natural oxide layer and possible surface contaminants. The test device is used to test the particle condition of the surface of the silicon wafer, and the silicon wafer meeting the requirements is selected as standby.

5. Bonding process: the silicon wafer injected with hydrogen ions in step 3 is bonded to the silicon wafer meeting the requirements in step 4, and a certain activating time is required. Then low-temperature annealing is performed for certain annealing time, and the annealing temperature is controlled between 100 and 350° C. After the annealing, the bonded wafer with injection is obtained.

6. Microwave splitting is performed on the bonded wafer: the microwave splitting technology of Shenyang Silicon-Based Technology Co., Ltd., is adopted, and the desired splitting process program is selected to split the bonded wafers. The SOI product is obtained.

7. Chamfering process: the 8-inch SOI is obtained by step 6, and then chamfering is performed to remove the edge oxide layer. However, due to the poor precision of a chamfering device and the uniqueness of the 8-inch silicon wafer, there are notches. The positions of the notches must be flattened (special requirements on the silicon base), so the edge STIR of the chamfered SOI is greater than 0.3 μm, which does not meet product design requirements.

8. The 8-inch SOI is obtained by step 6, and the SOI wafer is recycled according to company regulations.

1. A method for changing an edge STIR of a silicon-on-insulator (SOI) by film coating, comprising: using a silicon wafer as a raw material, and performing oxidizing, injecting, bonding, splitting, and film coating in sequence; wherein the front surface and back surface of the SOI cannot be scratched in the film coating process using a film coating device; when the device adsorbs the silicon wafer, the silicon wafer cannot be dropped; if a blue film is used, the required thickness of the blue film is 0-0.5 mm; the film is coated to the back surface of the silicon wafer; and at this point, the film exists on the back surface of the silicon wafer;
then an oxide layer on the edge of the front surface of the silicon wafer is removed by concentrated hydrofluoric acid; at this point, the film exists on the back surface of the silicon wafer, and thus the back surface of the SOI cannot be damaged; the film on the back surface of the SOI is removed by concentrated SC1, then washing is performed by SC1 and SC2, the edge STIR of the SOI is tested by a device, and at this point, the STIR is smaller than 0.3 μm.

2. The method for changing an edge STIR of an SOI by film coating according to claim 1, wherein the oxidizing process comprises: oxidizing one side surface of the silicon wafer raw material to obtain the silicon wafer with an oxide layer, then cleaning to remove surface contaminants, then testing the surface particle condition, a thickness of the oxide layer and other various parameters of the silicon wafer with the oxide layer by using a test device, and selecting the silicon wafer meeting the requirements as standby.

3. The method for changing an edge STIR of an SOI by film coating according to claim 2, wherein the injecting process comprises: injecting H⁺ into the silicon wafer with the oxide layer and injecting to the desired depth of a product; injecting according to the specific injection conditions, including requirements on energy, a dose, a beam size and an angle, and after the injection, cleaning comprising: using concentrated sulfuric acid, SC1 and SC2 for cleaning; in order to remove surface contaminants, testing surface particles, geometric parameters and other various parameters of the silicon wafer with the oxide layer by using a test device, and selecting the silicon wafer meeting requirements as standby.

4. The method for changing an edge STIR of an SOI by film coating according to claim 3, wherein the bonding step comprises: preparing another silicon wafer, which is an oxide wafer or a polished wafer, selecting a resistivity and a crystal orientation of the another silicon wafer according to requirements, after cleaning the surface of the another silicon wafer to remove a surface natural oxide layer and surface layer contaminants, testing the surface particle condition of the silicon wafer by using the test device, and bonding the silicon wafer meeting the requirements to the silicon wafer subjected to injection, using certain activating time for the two wafers, and performing low-temperature annealing at 100-350° C. on the obtained bonded wafer, thereby obtaining the bonded wafer with injection.

5. The method for changing an edge STIR of an SOI by film coating according to claim 4, wherein the splitting process comprises: placing the bonded wafer into a splitting machine, and processing with the following splitting process: raising the temperature of the silicon wafer in a cavity to 100-200° C., and performing temperature preservation for 10-30 min; turning on a microwave magnetic control head for splitting for 1-10 min, and obtaining an SOI product after splitting.

6. The method for changing an edge STIR of an SOI by film coating according to claim 5, wherein the low-temperature annealing is that low-temperature annealing is performed after bonding and before splitting, and a temperature for the low-temperature annealing is 100-300° C. for 2-5 hours.
